(19) United States
(12) Patent Application Publication
(10) Pub. No.: US 2013/0099393 A1
(43) Pub. Date: Apr. 25, 2013

(54) Stacked Semiconductor Package

(71) Applicants: Jin Wook Jeong, Chungcheongnam-do (KR); Jin Ho Kim, Chungcheongbuk-do (KR)

(72) Inventors: Jin Wook Jeong, Chungcheongnam-do (KR); Jin Ho Kim, Chungcheongbuk-do (KR)

(73) Assignee: Hana Micron Inc., Asan-si (KR)

(21) Appl. No.: 13/805,992

(22) PCT Filed: Jun. 15, 2011
(86) PCT No.: PCT/KR2011/004378

§ 371 Date: Dec. 20, 2012

(30) Foreign Application Priority Data
Jun. 22, 2010 (KR) 10-2010-0059140

(51) Int. Cl. H01L 23/49

(52) U.S. Cl. CPC H01L 23/49
USPC 257/777

(57) ABSTRACT

Provided is a stacked semiconductor package. The present invention includes: a substrate having first and second connective pads provided on an upper surface thereof; a first cascade chip laminate which is loaded on the substrate and in which a plurality of first semiconductor chips are stacked in multiple stages to externally expose a first bonding pad wire-bonded through the first connective pad and a first conductive wire; a second cascade chip laminate in which a plurality of second semiconductor chips are stacked in the multiple stages to externally expose a second bonding pad wire-bonded through the second connective pad and a second conductive wire to an area corresponding to the first bonding pad; and a joint part for joining the first cascade chip laminate and the second cascade chip laminate.

### TECHNICAL FIELD

The present invention relates to a stacked semiconductor package, and, more particularly, to a stacked semiconductor package in which a plurality of semiconductor chips stacked in a height direction on a substrate is disposed without conversion in direction so that all of bonding pads formed on the upper surface thereof face the same direction, and wire bonding may be performed at the same position without any change in position using a wire bonding machine.

### BACKGROUND ART

With the recent advancement of the semiconductor industry and the various demands of users, electronic devices are manufactured to be much smaller and lighter, and to have larger capacities and perform multiple functions, and techniques for packaging semiconductor chips used in such electronic devices are intended to form the same or different semiconductor chips into a single unit package depending on the needs.

Chipscale packages wherein the size of a semiconductor package is about 110˜120% of the size of a semiconductor chip or die and stacked semiconductor packages comprising a plurality of semiconductor chips stacked to increase the data capacity and the processing speed of the semiconductor devices have been developed.

In the case of a stacked semiconductor package comprising a plurality of semiconductor chips which are stacked, high technology for connecting bonding pads of stacked semiconductor chips and connective pads of a substrate using conductive wires is required.

Thus, to increase data capacity and processing speed by stacking more semiconductor chips in a limited space, the thickness of semiconductor chips has been reduced, and thereby semiconductor chips these days have a thickness of 50˜100 μm.

FIG. 7 illustrates a conventional stacked semiconductor package. The conventional stacked semiconductor package 1 includes a first cascade chip laminate 20 configured such that a plurality of semiconductor chips 21 is obliquely stacked in a stepped shape on a substrate 10 and bonding pads 22 are thus externally exposed to one side of the top of each of the chips, and a second cascade chip laminate 30 configured such that a plurality of semiconductor chips 31 is obliquely stacked in a stepped shape in the opposite direction on the first cascade chip laminate 20 and thus bonding pads 32 are externally exposed to the other side of the top of each of the chips.

The bonding pads 22, 32 of the semiconductor chips 21, 31 of the first and second cascade chip laminates 20, 30 are wire-bonded to connective pads 12, 13 provided on the upper surface of the substrate 10 by means of a plurality of conductive wires 23, 33.

In FIG. 7, the reference numeral 14 designates solder balls provided on the lower surface of the substrate, and the reference numeral 50 designates a molding unit made of a resin on the substrate.

However, the conventional stacked semiconductor package 1 is problematic because, in the course of stacking the semiconductor chips in a height direction and wire-bonding the stacked semiconductor chips to the substrate, the plurality of semiconductor chips 21 should be stacked on the upper surface of the substrate 10 so as to expose the bonding pads 22 toward one side, that is, the right side in the drawing, thus forming the first cascade chip laminate 20, after which the plurality of semiconductor chips 31 should be stacked on the upper surface of the first cascade chip laminate 20 so as to expose the bonding pads toward the other side, that is, the left side in the drawing in the direction opposite to the semiconductor chips 21 positioned thereunder, thus forming the second cascade chip laminate 30, undesirably making it very difficult to convert the placing direction of the upper semiconductor chips relative to the lower semiconductor chips by 180°, resulting in decreased process productivity.

### DISCLOSURE

### Technical Problem

Accordingly, the present invention has been made keeping in mind the above problems occurring in the related art, and an object of the present invention is to provide a stacked semiconductor package in which a plurality of semiconductor chips stacked in a height direction on a substrate is disposed without conversion in the direction so that all of bonding pads formed on the upper surface thereof face the same direction, thus simply performing bonding of the semiconductor chip package using a wire bonding machine.

### Technical Solution

In order to accomplish the above object, the present invention provides a stacked semiconductor package, comprising a substrate having a first connective pad and a second connective pad formed on an upper surface thereof; a first cascade chip laminate comprising a plurality of first semiconductor chips stacked on the substrate so as to externally expose first bonding pads which are wire-bonded to the first connective pad of the substrate via a first conductive wire; a second cascade chip laminate comprising a plurality of second semiconductor chips which are stacked so that second bonding pads which are wire-bonded to the second connective pad of the substrate via a second conductive wire are externally exposed at positions corresponding to the first bonding pads; and a joint part for joining the first cascade chip laminate and the second cascade chip laminate to each other.

Preferably, the joint part includes a film layer having film over wire (FOW) properties to embed the first bonding pad of an uppermost semiconductor chip of the first cascade chip laminate and an upper portion of the first conductive wire wire-bonded thereto.

Preferably, the joint part includes a spacer having a predetermined thickness provided between the first cascade chip laminate and the second cascade chip laminate which are adhered to each other via an adhesive layer while externally exposing the first bonding pad of the uppermost semiconductor chip of the first cascade chip laminate.

More preferably, the spacer includes an extension part which extends up to a region corresponding to the second bonding pad of a lowermost semiconductor chip of the second cascade chip laminate and is spaced apart from a loop at a top of the first conductive wire.

Preferably, a reinforcement part is provided via filling between the first bonding pads of the semiconductor chips of the first cascade chip laminate and a lower surface of the second cascade chip laminate so as to support and reinforce the second cascade chip laminate.

Preferably, the substrate includes a molding unit which protects the first cascade chip laminate and the second cascade chip laminate from an external environment.

### Advantageous Effects

According to the present invention, when a second cascade chip laminate comprising second semiconductor chips is formed on a first cascade chip laminate comprising a plurality of stacked first semiconductor chips by means of a joint part, the second semiconductor chips of the second cascade chip laminate can be disposed in the same direction as the first bonding pads of the first semiconductor chips without conversion in direction. Thereby, a process of stacking the second semiconductor chips of the second cascade chip laminate on the first cascade chip laminate can be simply and rapidly carried out without conversion in the direction, and a wire bonding process can be performed at the same position without any change in the position, thus reducing the length of time required for performing stacking of chips and wire bonding, consequently increasing process productivity.

### DESCRIPTION OF DRAWINGS

FIG. 1 is a cross-sectional view illustrating a stacked semiconductor package according to a first embodiment of the present invention;

FIG. 2 is a cross-sectional view illustrating a stacked semiconductor package according to a second embodiment of the present invention;

FIG. 3 is a cross-sectional view illustrating a stacked semiconductor package according to a third embodiment of the present invention;

FIG. 4 is a cross-sectional view illustrating a stacked semiconductor package according to a fourth embodiment of the present invention;

FIG. 5 is a cross-sectional view illustrating a stacked semiconductor package according to a fifth embodiment of the present invention;

FIG. 6 is a cross-sectional view illustrating a stacked semiconductor package according to a sixth embodiment of the present invention; and

FIG. 7 is a cross-sectional view illustrating a conventional stacked semiconductor package.

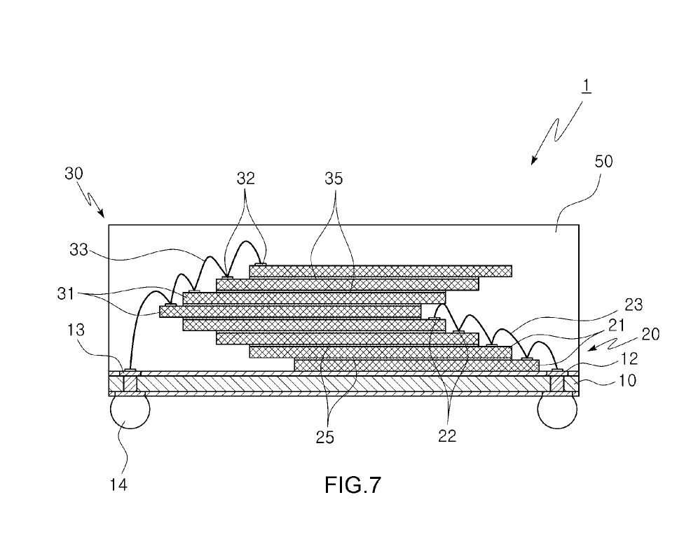

### MODE FOR INVENTION

Hereinafter, a detailed description will be given of the preferred embodiments of the present invention with reference to the appended drawings.

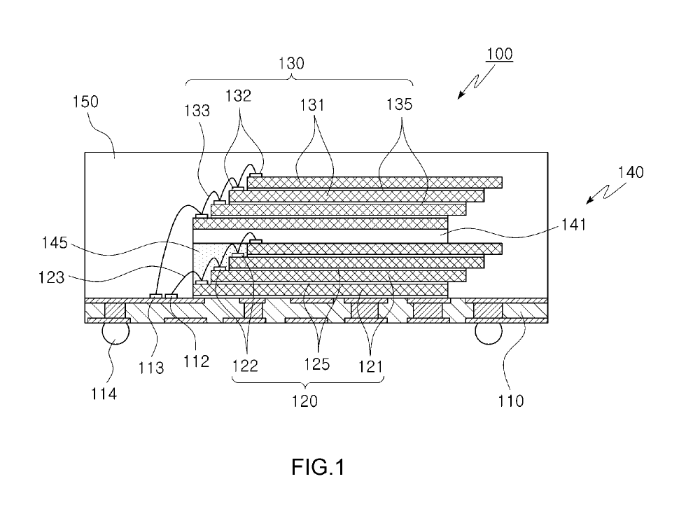

According to a first embodiment of the present invention, as illustrated in FIG. 1, a stacked semiconductor package 100 includes a substrate 110, a first cascade chip laminate 120, a second cascade chip laminate 130, first and second conductive wires 123, 133, and a joint part 140.

The substrate 110 includes a first connective pad 112 which is wire-bonded to the end of the first conductive wire 123 and a second connective pad 113 which is wire-bonded to the end of the second conductive wire 133 on the upper surface thereof on which the first cascade chip laminate 120 and the second cascade chip laminate 130 are continuously stacked in a height direction, and the first connective pad 112 and the second connective pad 113 are disposed adjacent to each other so as to be wire-bonded to first bonding pads 122 and second bonding pads 132 which are exposed to face the same direction.

The substrate 110 has solder balls 114 applied on ball lands on the lower surface thereof so as to be electrically connected to a main board (not shown), and thereby may be provided as a printed circuit board which may be mounted on the main board.

The first cascade chip laminate 120 includes a plurality of first semiconductor chips 121 stacked in two or more layers on the upper surface of the substrate 110, and the plurality of first semiconductor chips 121 includes the first bonding pads 122 which are wire-bonded to the first conductive wire 123 on the upper surface of one end of each thereof, and may be stacked in a stepped shape tilted to the left side in the drawing by means of an adhesive layer 125 so that the first bonding pads 122 are externally exposed.

The second cascade chip laminate 130 is a stack structure provided on the first cascade chip laminate 120 via the joint part 140, and includes a plurality of second semiconductor chips 131 as in the first cascade chip laminate, and the plurality of second semiconductor chips 131 includes the second bonding pads 132 which are wire-bonded to the second conductive wire 133 on the upper surface of one end of each thereof, and may be stacked in a stepped shape tilted to the left side in the drawing by means of an adhesive layer 135 so that the second bonding pads 122 are externally exposed.

The semiconductor chips 131 may be stacked without conversion in the direction as in the configuration form of the first semiconductor chips 132 so that the second bonding pads are located at positions corresponding to the first bonding pads 122 of the first semiconductor chips 132.

Thus, the second semiconductor chips 131 of the second cascade chip laminate 130 formed via the joint part 140 on the first cascade chip laminate 120 are stacked to have the same stack configuration as the first semiconductor chips 121 of the first cascade chip laminate 120 without conversion in the direction, thereby simplifying the process of stacking the plurality of semiconductor chips and reducing the length of time required for performing the stacking process, resulting in increased process productivity.

The first and second semiconductor chips 121, 131 may include any one selected from among memory chips such as SRAM and DRAM, digital integrated circuit chips, RF integrated circuit chips, and base band chips, depending on the type of setting device to which the package is applied.

The joint part 140 is disposed between the uppermost semiconductor chip 121 of the first cascade chip laminate 120 and the lowermost semiconductor chip 131 of the second cascade chip laminate 130 and thus integratedly bonds the first cascade chip laminate 120 and the second cascade chip laminate 130 each having the stacked semiconductor chips so that the first and second bonding pads 122, 132 are exposed in the same direction.

As illustrated in FIG. 1, the joint part 140 may include a film layer 141 having film over wire (FOW) properties so as to embed the first bonding pad 122 of the uppermost semiconductor chip 121 of the first cascade chip laminate 120 and the upper portion of the first conductive wire 123 which wire-bonds the first connective pad 112 of the substrate 110 thereto.

The FOW properties of the film layer 141 may manifest gel properties while having viscosity which does not have an interference influence on the semiconductor chip and the conductive wire.

Accordingly, the joint part 140 including the film layer 141 having FOW properties has gel properties before being cured, and thus has an adhesive force adapted to easily adhere the upper surface of the uppermost semiconductor chip 121 of the first cascade chip laminate 120 to the lower surface of the lowermost semiconductor chip 131 of the second cascade chip laminate 130.

The film layer 141 may be formed using a material such as a synthetic polymeric resin as a material having adhesive force.

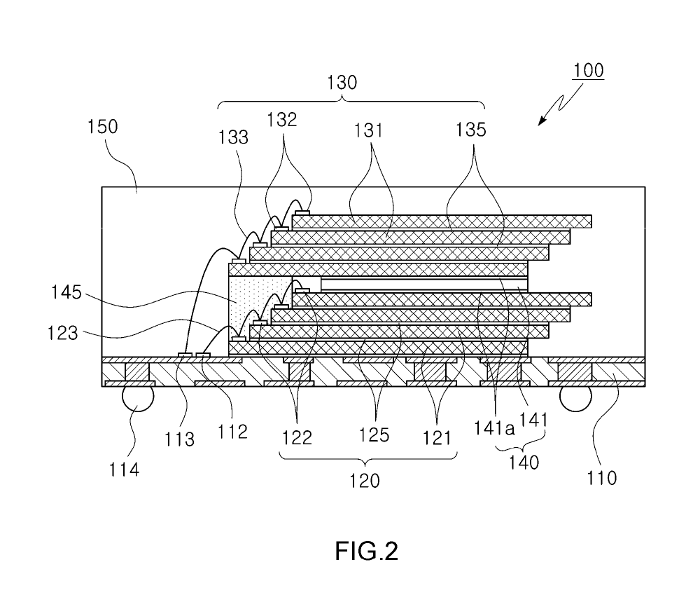

As illustrated in FIG. 2, the joint part 140 may include a spacer 142 having a predetermined thickness which externally exposes the first bonding pad 122 of the uppermost semiconductor chip 121 of the first cascade chip laminate 120 and also which adheres the upper surface of the uppermost semiconductor chip 121 of the first cascade chip laminate 120 to the lower surface of the lowermost semiconductor chip 131 of the second cascade chip laminate 130 via an adhesive layer 141a.

Herein, the thickness of the spacer 142 is preferably determined within a range in which a loop at the top of the first conductive wire 123 which is wire-bonded to the first bonding pad 122 does not come into contact with the lower surface of the second semiconductor chip 131.

Such a spacer may be made of silicone or may be provided in the form of a film.

Also, as illustrated in FIGS. 1 and 2, the empty space defined between the first bonding pads 122 of the semiconductor chips 121 of the first cascade chip laminate 120 and the lower surface of the second cascade chip laminate 130 may be filled with a resin such as epoxy so as to minimize cracking and movement of the semiconductor chips due to an external force generated upon wire bonding of the second cascade chip laminate 130, thus forming a reinforcement part 145 which supports and reinforces the second cascade chip laminate 130.

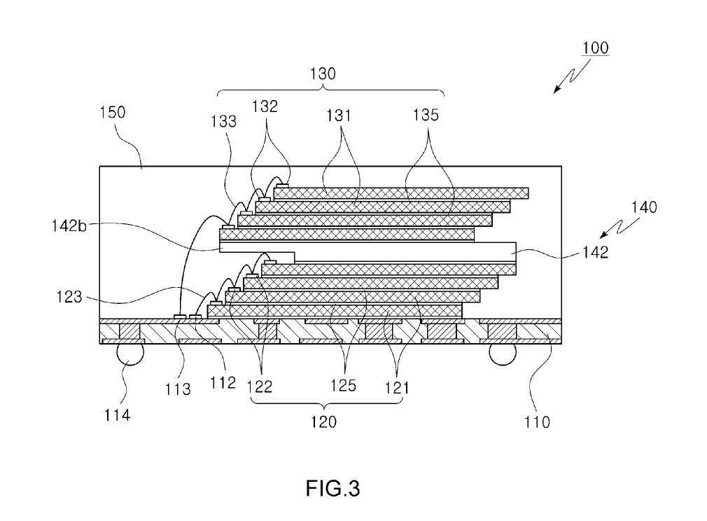

Also, as illustrated in FIG. 3, one end of the spacer 142 corresponding to the first bonding pad 122 may be provided with an extension part 142b which is spaced apart from the loop at the top of the first conductive wire 123 while extending up to a region corresponding to the second bonding pad 132 of the lowermost semiconductor chip of the second cascade chip laminate 130 so as to minimize cracking and movement of the semiconductor chips due to an external force generated upon wire bonding of the second cascade chip laminate 130.

The first conductive wire 123 wire-bonds the first bonding pads 122 formed to be externally exposed on the upper surface of one end of each of the first semiconductor chips 121 to the first connective pad 112 formed on the upper surface of the substrate 110 using a wire bonding machine so that the first semiconductor chips 121 of the first cascade chip laminate 120 are electrically connected to the substrate 110.

The second conductive wire 133 wire-bonds the second bonding pads 132 formed to be externally exposed on the upper surface of one end of each of the second semiconductor chips 131 to the second connective pad 113 formed on the upper surface of the substrate 110 using a wire bonding machine so that the second semiconductor chips 131 of the second cascade chip laminate 130 are electrically connected to the substrate 110.

Upon wire bonding using the first and second conductive wires 123, 133, because the semiconductor chips are disposed without conversion in the direction so that all of the first and second bonding pads wire-bonded with such wires are exposed in the same direction, the bonding process may be performed as it is without the need to rotate the semiconductor chips by 180° to perform the bonding process as in the conventional case.

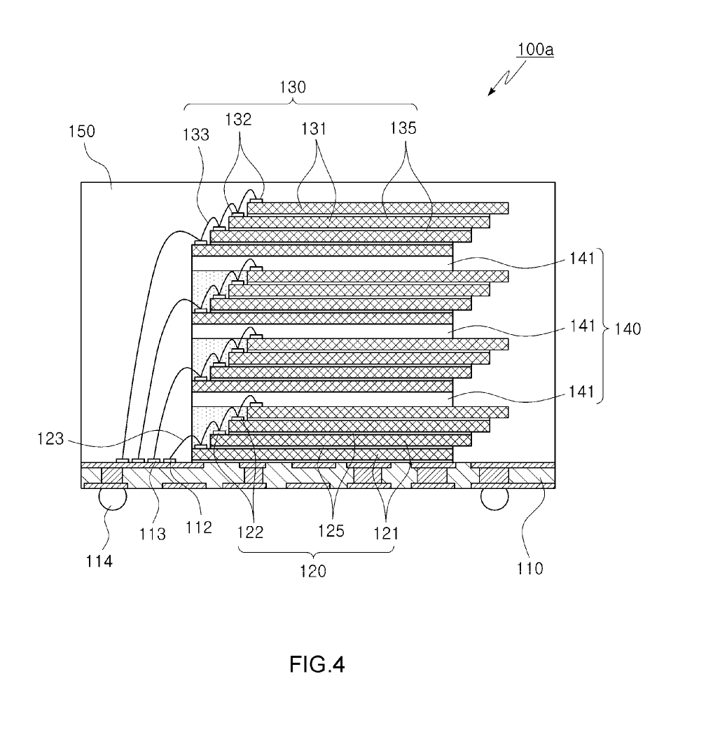

As illustrated in FIGS. 1 to 3, the first and second cascade chip laminates 120, 130 are illustratively explained such that two chip laminates each formed by stacking four semiconductor chips are vertically provided in two layers thus forming a stacked semiconductor package 100 having a total of eight semiconductor chips, but the present invention is not limited thereto. As illustrated in FIG. 4, four chip laminates each formed by stacking four semiconductor chips may be vertically disposed in four layers thus forming a stacked semiconductor package 100a having a total of sixteen semiconductor chips which are continuously stacked.

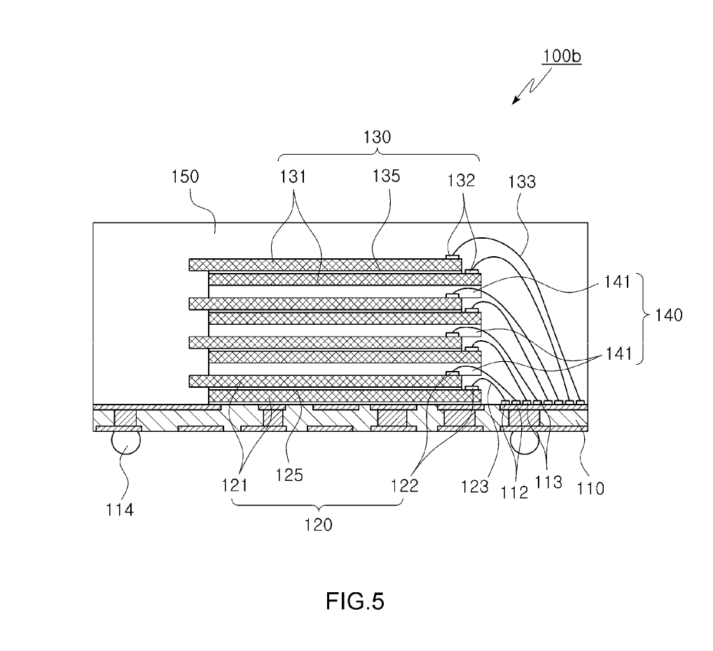

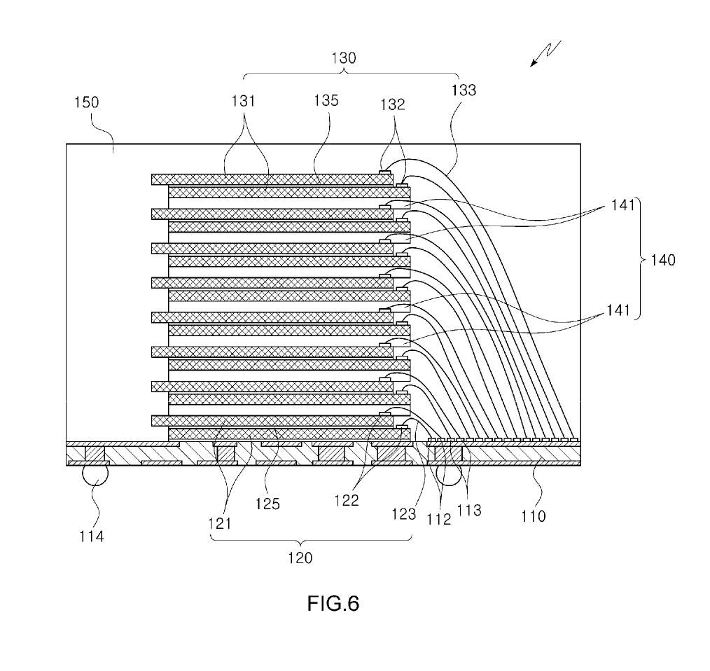

As illustrated in FIG. 5, the first and second cascade chip laminates 120, 130 may be configured such that two chip laminates each formed by stacking two semiconductor chips may be vertically disposed in four layers thus forming a stacked semiconductor package 100b having a total of eight semiconductor chips which are stacked, or alternatively as illustrated in FIG. 6, eight chip laminates each formed by stacking two semiconductor chips may be vertically disposed in eight layers thus forming a stacked semiconductor package 100c having a total of sixteen semiconductor chips which are continuously stacked.

The substrate 110 includes a molding unit 150 made of a resin sealing material such as an epoxy molding compound to cover the first cascade chip laminate 120, the second cascade chip laminate 130, and the first and second conductive wires 123, 133 so as to protect them from an external environment such as corrosion or external physical damage, thereby forming a single package.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A stacked semiconductor package, comprising:
a substrate having a first connective pad and a second connective pad formed on an upper surface thereof;
a first cascade chip laminate comprising a plurality of first semiconductor chips stacked on the substrate so as to externally expose first bonding pads which are wire-bonded to the first connective pad of the substrate via a first conductive wire;
a second cascade chip laminate comprising a plurality of second semiconductor chips which are stacked so that second bonding pads which are wire-bonded to the second connective pad of the substrate via a second conductive wire are externally exposed at positions corresponding to the first bonding pads; and
a joint part for joining the first cascade chip laminate and the second cascade chip laminate to each other.

2. The stacked semiconductor package of claim 1, wherein the joint part includes a film layer having film over wire (FOW) properties to embed the first bonding pad of an uppermost semiconductor chip of the first cascade chip laminate and an upper portion of the first conductive wire wire-bonded thereto.

3. The stacked semiconductor package of claim 1, wherein the joint part includes a spacer having a predetermined thickness provided between the first cascade chip laminate and the second cascade chip laminate which are adhered to each other via an adhesive layer while externally exposing the first bonding pad of the uppermost semiconductor chip of the first cascade chip laminate.

4. The stacked semiconductor package of claim 3, wherein the spacer includes an extension part which extends up to a region corresponding to the second bonding pad of a lowermost semiconductor chip of the second cascade chip laminate and is spaced apart from a loop at a top of the first conductive wire.

5. The stacked semiconductor package of claim 1, wherein a reinforcement part is provided via filling between the first bonding pads of the semiconductor chips of the first cascade chip laminate and a lower surface of the second cascade chip laminate so as to support and reinforce the second cascade chip laminate.

6. The stacked semiconductor package of claim 1, wherein the substrate includes a molding unit which protects the first cascade chip laminate and the second cascade chip laminate from an external environment.
